(19) United States
(12) Patent Application Publication
(10) Pub. No.: US 2025/0038059 A1
(43) Pub. Date: Jan. 30, 2025

(54) MODULAR INTERCONNECTION UNIT, SEMICONDUCTOR PACKAGE AND METHOD FOR MAKING THE SAME

(71) Applicant: JCET STATS ChipPAC Korea Limited, Incheon (KR)

(72) Inventors: HyeonChul LEE, Seoul (KR); KyoungHee PARK, Seoul (KR); KyungHwan KIM, Seoul (KR); SeungHyun LEE, Incheon (KR)

(21) Appl. No.: 18/749,647

(22) Filed: Jun. 21, 2024

(30) Foreign Application Priority Data
Jul. 28, 2023 (CN) 202310942587.7

(51) Int. Cl. H01L 23/31; H01L 21/56; H01L 21/683; H01L 21/78; H01L 23/00; H01L 23/48; H01L 23/552; H01L 25/065

(52) U.S. Cl. CPC H01L 23/3128; H01L 21/563; H01L 21/565; H01L 21/6838; H01L 21/78; H01L 23/481; H01L 23/552; H01L 24/16; H01L 24/81; H01L 25/0657; H01L 2224/16225; H01L 2224/81815; H01L 2225/06537; H01L 2924/3025

(57) ABSTRACT

A modular interconnection unit, a semiconductor package and a method for making the same are provided. The method includes: providing a first sub-package including a first substrate, at least one first interconnection pattern, and at least one first electronic component; mounting at least one modular interconnection unit on the first substrate, wherein the modular interconnection unit includes a dielectric layer, at least one conductive via passing through the dielectric layer, at least one conductive bump raised from an upper surface of the dielectric layer, and a protection layer covering the conductive bump and having a flat upper surface, and the conductive via is electrically coupled with the first interconnection pattern; forming a first encapsulant on the upper surface of the first substrate; removing a portion of the protection layer to expose an upper surface of the conductive bump; and mounting a second sub-package above the first encapsulant.

### TECHNICAL FIELD

The present application generally relates to semiconductor technology, and more particularly, to a modular interconnection unit, a semiconductor package, and a method for making the same.

### BACKGROUND OF THE INVENTION

The semiconductor industry is constantly faced with complex integration challenges as consumers want their electronics to be smaller, faster and higher performance with more and more functionalities packed into a single device. One of the solutions is Package-on-Package (POP). PoP is a type of packaging method that combines two or more integrated circuit (IC) packages together. In a typical PoP, two or more packages are vertically connected (i.e., stacked) via vertical interconnection units that can direct signals between them. A POP assembly can more efficiently use space, and reduce lengths of signal paths between the packages. Thus, a better electrical performance can be achieved, as the shorter signal path length may reduce noises and cross talks in integrated circuits and promote faster signal response. However, the process for forming the POP assembly is complex, and the yield is still low.

Therefore, a need exists for improvements to the manufacturing method of semiconductor packages.

### SUMMARY OF THE INVENTION

An objective of the present application is to provide a method for making a semiconductor package with higher reliability.

According to an aspect of the present application, a method for forming a semiconductor package is provided. The method may include: providing a first sub-package including a first substrate, at least one first interconnection pattern formed in the first substrate, and at least one first electronic component mounted on an upper surface of the first substrate; mounting at least one modular interconnection unit on the upper surface of the first substrate, wherein the modular interconnection unit includes a dielectric layer, at least one conductive via passing through the dielectric layer, at least one conductive bump disposed on the dielectric layer and raised from an upper surface of the dielectric layer, and a protection layer covering the conductive bump and having a flat upper surface, and wherein the conductive via is electrically coupled with the first interconnection pattern; forming a first encapsulant on the upper surface of the first substrate to encapsulate the first electronic component and the modular interconnection unit; removing a portion of the protection layer to expose an upper surface of the conductive bump; and mounting a second sub-package above the first encapsulant, wherein the second sub-package includes a second substrate, at least one second interconnection pattern formed in the second substrate, and at least one second electronic component mounted on an upper surface of the second substrate, and the second interconnection pattern is electrically coupled with the conductive bump.

According to another aspect of the present application, a semiconductor package is provided. The semiconductor package may include: a first sub-package including a first substrate, at least one first interconnection pattern formed in the first substrate, and at least one first electronic component mounted on an upper surface of the first substrate; at least one modular interconnection unit mounted on the upper surface of the first substrate, wherein the modular interconnection unit includes a dielectric layer, at least one conductive via passing through the dielectric layer, at least one conductive bump disposed on the dielectric layer and raised from an upper surface of the dielectric layer, and a protection layer disposed on the dielectric layer and partially covering the conductive bump, wherein the conductive via is electrically coupled with the first interconnection pattern, and wherein an upper surface of the conductive bump is exposed from the protection layer; a first encapsulant disposed on the upper surface of the first substrate, wherein the first encapsulant surrounds the first electronic component and the modular interconnection unit, and exposes the upper surface of the conductive bump; and a second sub-package mounted above the first encapsulant, wherein the second sub-package includes a second substrate, at least one second interconnection pattern formed in the second substrate, and at least one second electronic component mounted on an upper surface of the second substrate, and the second interconnection pattern is electrically coupled with the conductive bump.

According to still another aspect of embodiments of the present application, a modular interconnection unit is provided. The modular interconnection unit may include: a dielectric layer; at least one conductive via passing through the dielectric layer; at least one conductive bump disposed on the dielectric layer and raised from an upper surface of the dielectric layer; and a protection layer disposed on the dielectric layer, wherein the protection layer covers the conductive bump and has a flat upper surface.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 is a cross-sectional view illustrating an interconnection unit.

FIG. 2 is a cross-sectional view illustrating a modular interconnection unit according to an embodiment of the present application.

FIGS. 3A to 3D are cross-sectional views illustrating various steps of a method for making a modular interconnection unit according to an embodiment of the present application.

FIGS. 4A to 4I are cross-sectional views illustrating various steps of a method for making a semiconductor package according to an embodiment of the present application.

FIGS. 5A to 5D are cross-sectional views illustrating various steps of a method for making a semiconductor package according to another embodiment of the present application.

FIG. 6 is a cross-sectional view illustrating a semiconductor package according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

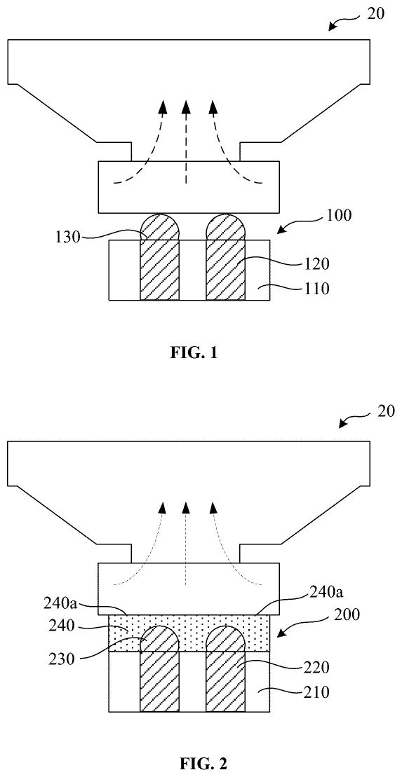

FIG. 1 illustrates a cross-sectional view of a modular interconnection unit 100. The modular interconnection unit 100 can be used in a Package-on-Package (POP) assembly to direct signals between two integrated circuit (IC) packages. The modular interconnection unit 100 includes a dielectric body 110, at least one conductive via 120 passing through the dielectric body 110, and at least one conductive bump 130 formed on the dielectric body 110. In a process for forming a PoP assembly, the modular interconnection unit 100 is first picked up using a vacuum pick-and-place tool 20 as shown in FIG. 1 and then mounted on a lower package. Afterwards, an upper package is mounted above the modular interconnection unit 100 to form the POP assembly. However, as the conductive bump 130 is raised from an upper surface of the dielectric layer 120, a vacuum leakage may occur between a vacuum nozzle of the vacuum pick-and-place tool 20 and the conductive bumps 130, and the modular interconnection unit 100 may drop off the tool 20 during the pick-and-place process, resulting a low yield and low units-per-hour (UPH) value.

To address at least one of the above problems, a new modular interconnection unit is provided in the embodiments of the present application. In the modular interconnection unit, a protection layer is formed on an upper surface of the modular interconnection unit to cover the raised conductive bumps. As the protection layer is formed to have a flat upper surface, there would be no vacuum leakage between the vacuum pick-and-place tool and the modular interconnection unit.

Referring to FIG. 2, a modular interconnection unit 200 is illustrated according to an embodiment of the present application.

The modular interconnection unit 200 includes a dielectric layer 210 and at least one conductive via 220 passing through the dielectric layer 210. In some embodiments, the dielectric layer 210 may be a laminate core of a printed wiring board (PWB), and the conductive via 220 may include one or more of Cu, Al, Sn, Ni, Au, Ag, Ti, W, or other suitable electrically conductive material. In some embodiments, the modular interconnection unit 200 may be a semiconductor interposer and can be fabricated using any suitable IC manufacturing processes. For example, the dielectric layer 210 may include silicon and any other semiconductor-based materials, and the conductive via 220 may be formed by filling through-silicon vias (TSVs) with conductive materials.

The modular interconnection unit 200 further includes at least one conductive bump 230 disposed on the dielectric layer 210. The conductive bump 230 may be raised from an upper surface of the dielectric layer 210 and is electrically connected with the conductive via 220. In the example shown in FIG. 2, the conductive bump 230 is illustrated as solder bumps, but the present application is not limited thereto. In some other embodiments, the conductive bump 230 may include a conductive pillar such as copper pillar. The conductive bump 230, together with the conductive via 220, may be used for electrically connecting a lower package to an upper package in a POP assembly.

A protection layer 240 is formed on the dielectric layer 210. The protection layer 240 covers the conductive bump 230 and has a flat upper surface 240a. In some embodiments, the protection layer 240 may include a molding compound or resin, for example, an epoxy-based resin, but the scope of this application is not limited thereto. In some embodiments, a thickness of the protection layer 240 ranges from 105% to 200% (for example, 110%, 130%, 150%, 170% or 190%) of a height of the conductive bump. In some embodiments, a grinding process may be employed to planarize the upper surface 240a of the protection layer 240. As the upper surface 240a of the protection layer 240 is flat, the modular interconnection unit 200 can be easily picked up and placed at a desired location when the vacuum pick-and-place tool 20 applies a suction vacuum pressure on the upper surface 240a of the protection layer 240, as shown in FIG. 2.

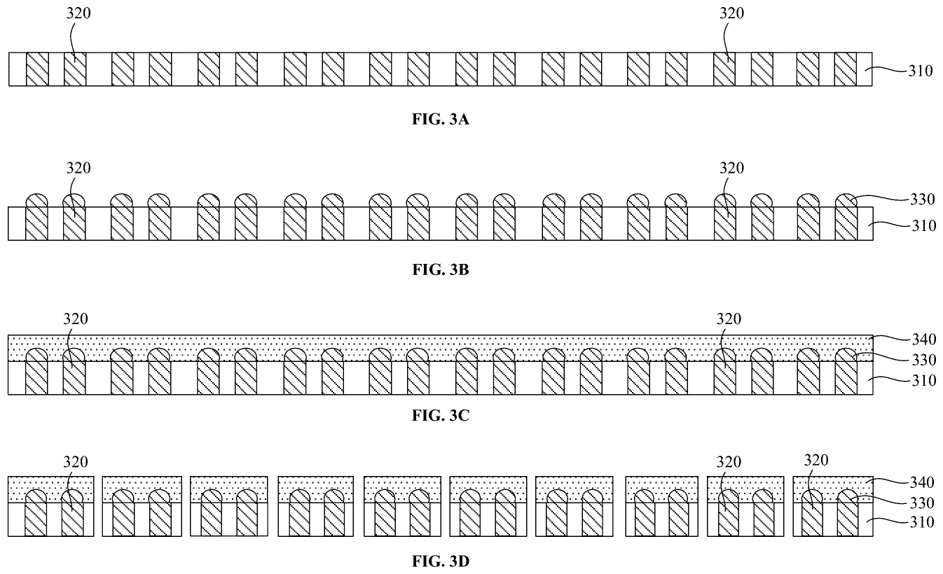

FIGS. 3A to 3D illustrate a process for making a modular interconnection unit according to an embodiment of the present application. The modular interconnection unit may be the same as or similar to the modular interconnection unit 200 of FIG. 2.

As shown in FIG. 3A, a dielectric layer or body 310 is provided. The dielectric layer 310 may be a laminate core of a printed wiring board, or include a semiconductor material. A plurality of through vias are formed in the dielectric layer 310 using laser drilling, mechanical drilling, deep reactive ion etching (DRIE), or other suitable process. Afterwards, a conductive material is deposited within the through vias to form a plurality of conductive vias 320. For example, the conductive vias 320 may be formed using an electrolytic plating, electroless plating, evaporation, or screen-printing process, and may include one or more of Cu, Al, Sn, Ni, Au, Ag, Ti, W, or other suitable electrically conductive material. The upper surface of each conductive via 320 is substantially flush or coplanar with the upper surface of the dielectric layer 310.

Referring to FIG. 3B, a plurality of conductive bumps 330 are formed on the dielectric layer 310, and are in contact with the plurality of conductive vias 320, respectively. In some embodiments, a solder material may be deposited on the upper surface of each conductive via 320, and then the solder material may be reflowed to form the conductive bump 330. In some other embodiments, a conductive pillar such as a copper pillar may be mounted on the upper surface of each conductive via 320.

Referring to FIG. 3C, a protection layer 340 is formed on the dielectric layer 310 to cover the conductive bumps 330. In some embodiments, the protection layer 340 may be formed using a molding process such as a compression molding process or an injection molding process. In some other embodiments, the protection layer 340 may be formed using paste printing, transfer molding, liquid encapsulant molding, vacuum lamination, spin coating, or other suitable processes. After the protection layer 340 is formed on the dielectric layer 310, a grinding process may be employed to planarize an upper surface of the protection layer 340. The protection layer 340 may be made of a polymer composite material, such as epoxy resin with filler, epoxy acrylate with filler, or polymer with proper filler, but the scope of this application is not limited thereto.

As the processes of FIGS. 3A to 3C are performed on a strip-type substrate, a singulation step is performed on the substrate strip in FIG. 3D to form a plurality of modular interconnection units. In some embodiments, a laser cutting process, a saw blading, an etching process, or any other suitable process known in the art can be employed to singulate the strip into individual units. The plurality of modular interconnection units may have a square, rectangular, hexagonal, or any other geometric shaped footprints as desired. Moreover, the footprints of the plurality of modular interconnection units may have same sizes and/or shapes, or may differ in size and/or shape.

According to another aspect of the present application, a method for forming a PoP type package is provided. The modular interconnection unit shown in FIG. 2 may be used in the PoP type package to provide connectivity between two sub-packages.

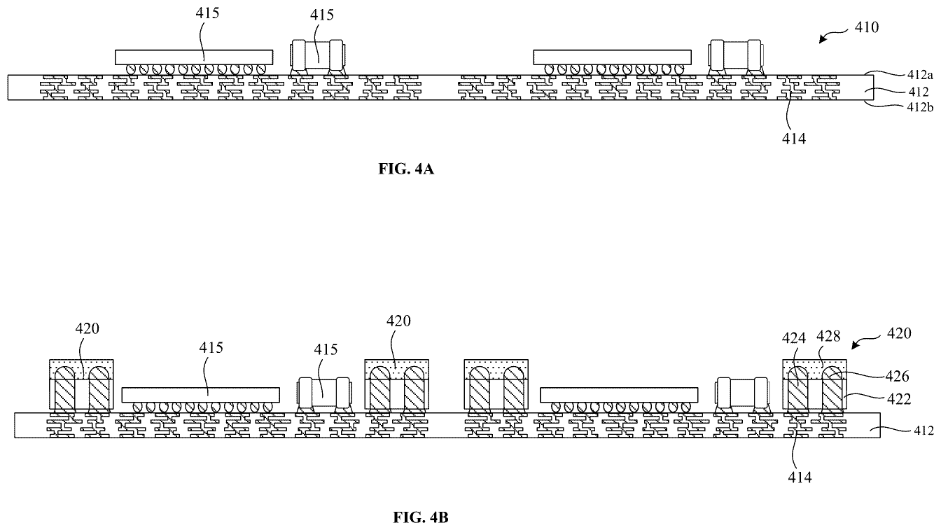

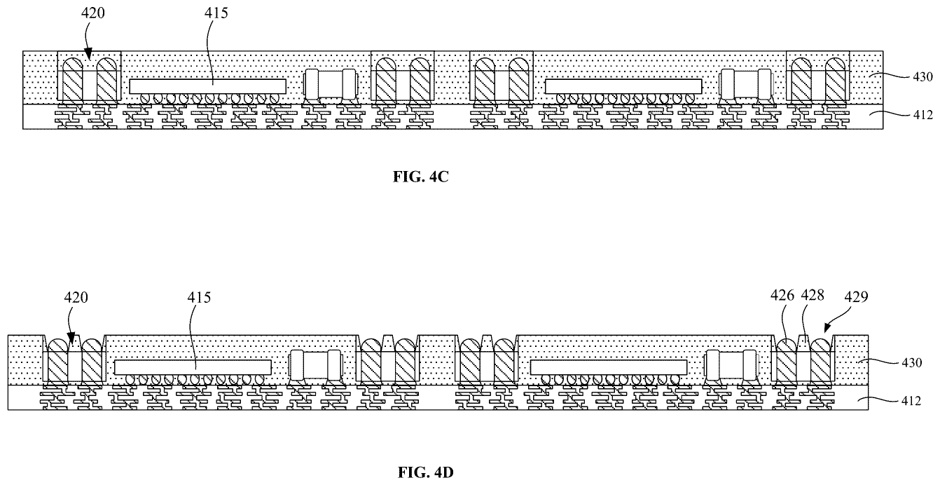

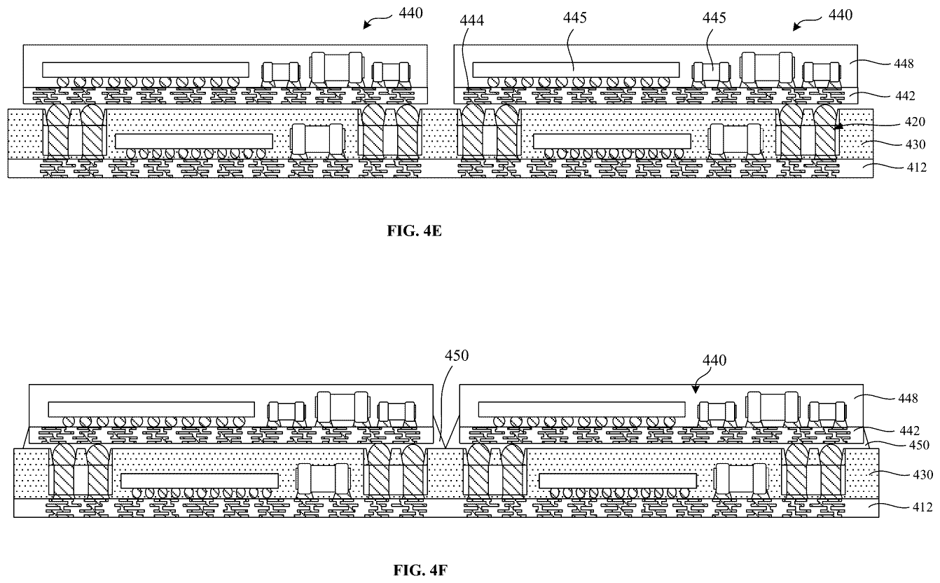

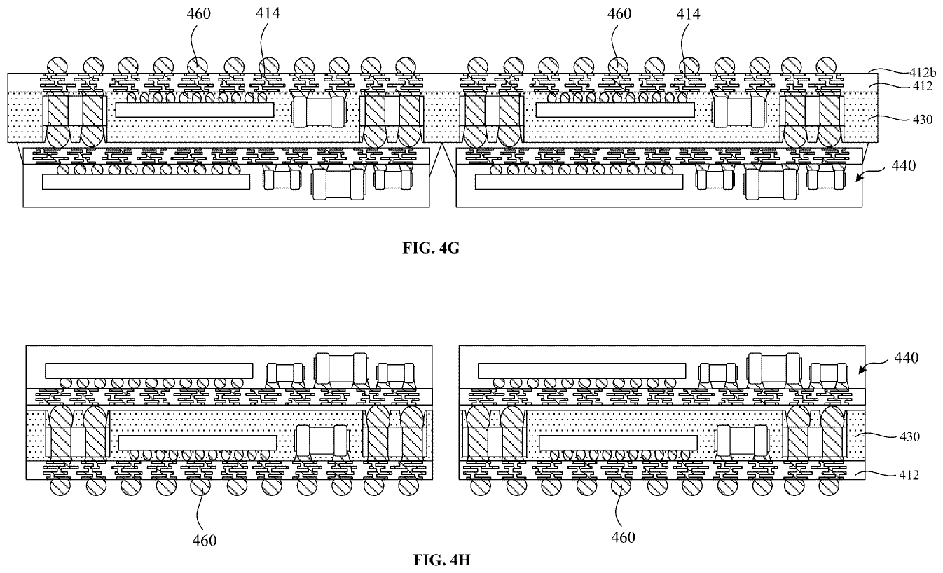

Referring to FIGS. 4A-4I, cross-sectional views illustrating a method for making a PoP type package are shown according to an embodiment of the present application.

As shown in FIG. 4A, a first sub-package 410 is provided. The first sub-package 410 may include a first substrate 412 having an upper surface 412a and a lower surface 412b, at least one first interconnection pattern 414 formed in the first substrate 412, and at least one first electronic component 415 mounted on an upper surface 412a of the first substrate 412.

Specifically, the first substrate 412 can provide support and connectivity for electronic components and devices mounted thereon. By way of example, the first substrate 412 may include a printed circuit board (PCB), a carrier substrate, a semiconductor substrate with electrical interconnections, or a ceramic substrate. However, the first substrate 412 is not to be limited to these examples. In other examples, the first substrate 412 may include a laminate interposer, a strip interposer, a leadframe, or other suitable substrates. To enhance manufacturing throughput, the first substrate 412 may include a plurality of predefined substrate units arranged in a strip manner, thereby allowing some manufacturing processes to be performed on all the substrate units in parallel. The first substrate 412 also includes a plurality of singulation areas, which can provide respective cutting areas to singulate the substrate units into individual substrate units.

As shown in FIG. 4A, the first substrate 412 may include a plurality of first interconnection patterns 414. The first interconnection patterns 414 can provide connectivity for electronic components mounted on the first substrate 412. The first interconnection patterns 414 may define pads, traces and plugs through which electrical signals or voltages can be distributed horizontally and vertically across the first substrate 412. For example, as shown in FIG. 4A, some of the first interconnection patterns 414 may provide a plurality of contact pads on the upper surface 412a and the lower surface 412b of the first substrate 412.

In addition, a plurality of first electronic components 415 are mounted on the upper surface 412a of the first substrate 412. The first electronic components 415 can be mounted on the front surface 412a of the first substrate 412 by flip-chip bonding or other suitable surface mounting techniques. For example, solder paste may be deposited or printed onto contact pads where the first electronic components 415 may be surface mounted. Then, the first electronic components 415 may be placed on the upper surface 412a of the first substrate 412 with terminals or contacts of the first electronic components 415 in contact with and over the solder paste. The solder paste may then be reflowed to mechanically and electrically couple the first electronic components 415 to the contact pads on the upper surface 412a of the first substrate 412.

The first electronic components 415 may include any of a variety of types of semiconductor dice, semiconductor packages, or discrete devices. For example, the first electronic components 415 may include an ultra-wideband (UWB) device, a digital signal processor (DSP), a microcontroller, a microprocessor, a network processor, a power management processor, an audio processor, a video processor, an RF circuit, a wireless baseband system on chip (SoC) processor, a sensor, a memory controller, a memory device, an application specific integrated circuit (ASIC), etc.

Referring to FIG. 4B, at least one modular interconnection unit 420 is mounted on the upper surface 412a of the first substrate 412.

The modular interconnection unit 420 may include a dielectric layer 422, at least one conductive via 424 passing through the dielectric layer 422, and at least one conductive bump 426 disposed on the dielectric layer 422 and raised from an upper surface of the dielectric layer 422. The modular interconnection unit 420 further includes a protection layer 428 covering the conductive bump 426 and having a flat upper surface. The conductive via 424 is electrically coupled with the first interconnection pattern 414 in the first substrate 412. The modular interconnection unit 420 may have a similar structure and configuration as the modular interconnection unit 200 shown in FIG. 2, and will not be elaborated herein.

In some embodiments, solder paste may be deposited or printed onto the first interconnection pattern 414 where the modular interconnection unit 420 may be surface mounted.

Then, a vacuum pick-and-place tool may be used to place the modular interconnection unit 420 to a location above the first interconnection pattern 414 with terminals of the modular interconnection unit 420 in contact with and over the solder paste. The solder paste may be reflowed to mechanically and electrically couple the modular interconnection unit 420 to the contact pads on the first interconnection pattern 414.

Referring to FIG. 4C, a first encapsulant 430 is formed on the upper surface of the first substrate 412 to encapsulate the first electronic component 415 and the modular interconnection unit 420.

In some embodiments, the first encapsulant 430 may be formed using a molding process such as a compression molding process or an injection molding process. In some other embodiments, the first encapsulant 430 may be formed using paste printing, transfer molding, liquid encapsulant molding, vacuum lamination, or other suitable process. The first encapsulant 430 may be made of a polymer composite material, such as epoxy resin with filler, epoxy acrylate with filler, or polymer with proper filler, but the scope of this application is not limited thereto.

In some embodiments, a grinding process may be performed on the first encapsulant 430 to planarize the first encapsulant 430 and expose the modular interconnection unit 420.

Referring to FIG. 4D, a portion of the protection layer 428 of the modular interconnection unit 420 is removed to expose an upper surface of the conductive bump 426.

In some embodiments, a laser ablation process may be employed to remove a portion of the protection layer 428 and form a trench 429 in the protection layer 428. The trench 429 exposes at least the upper surface of the conductive bump 426. The laser ablation technique can accurately control a shape and/or a depth of the trench 429. However, the present application is not limited thereto. In other embodiments, the trench 429 may be formed by a dry or wet etching process, or any other process known in the art so long as the material of the protection layer can be removed as desired. In some other embodiments, after forming the trench 429, a cleaning process for removing residuals at the trench may further be performed. It can be appreciated that, when multiple conductive bumps 426 are formed on the modular interconnection unit 420, the laser ablation process may not remove a portion of the protection layer 428 that separates adjacent conductive bumps 426 from each other, to maintain the electrical isolation of these conductive bumps 426. In that case, the laser ablation process may be more like a drilling process to remove the materials above the conductive bumps 426.

Referring to FIG. 4E, at least one second sub-package 440 is mounted on the modular interconnection unit 420 and above the first encapsulant 430.

The second sub-package 440 may include a second substrate 442, a second interconnection pattern 444 formed in the second substrate 442, and at least one second electronic component 445 mounted on an upper surface of the second substrate 442. Further, the second sub-package 440 may include a second encapsulant 448 encapsulating the second electronic component 445. The second electronic components 445 may include any of a variety of types of semiconductor dice, semiconductor packages, or discrete devices. For example, the first electronic components 415 may include a WiFi module, a digital signal processor (DSP), a memory device, a microcontroller, an RF circuit, etc. The second substrate 442 can provide support for the second electronic components 445, and the second interconnection pattern 444 can provide connectivity for the second electronic components 445.

After the second sub-package 440 is mounted on the modular interconnection unit 420, the second interconnection pattern 444 in the second sub-package 440 is electrically connected with the conductive bump 426 of the modular interconnection unit 420, such that the modular interconnection unit 420 can provide connectivity between the first sub-package 410 and the second sub-package 440.

In some embodiments, before the second sub-package 440 is mounted on the modular interconnection unit 420, a solder ball mounting (SBM) process may be performed to form an additional solder ball on the conductive bump 426, such that the solder ball may be raised further than the upper surface of the first encapsulant 430 to ensure contact with the second interconnection pattern 444 of the second sub-package 440.

Afterwards, referring to FIG. 4F, an underfill encapsulant 450 is formed between the first encapsulant 430 and the second substrate 442.

The underfill encapsulant 450 may fill in any gaps between the first encapsulant 430 and the second substrate 442 and optionally cover lateral surfaces of the second sub-package 440. The underfill encapsulant 450 may include a polymer composite material, such as epoxy resin, epoxy acrylate, or polymer with or without a filler. In some examples, the underfill encapsulant 450 is formed by depositing a fluid material at a location on the first encapsulant 430 that is next to the second substrate 442, and allowing capillary action to draw the fluid material into the space between the first encapsulant 430 and the second substrate 442.

In the example shown in FIG. 4F, the underfill encapsulant 450 also covers portions of lateral surfaces of the second substrate 442 and the second encapsulant 448. The underfill encapsulant 450 may provide mechanical support to the interconnection between the first sub-package 410 and the second sub-package 440, helping to mitigate the risk of crack or delamination due to differential thermal expansion between first sub-package 410 and the second sub-package 440.

Afterwards, referring to FIG. 4G, the package shown in FIG. 4F is flipped over, and a plurality of external interconnection bumps 460 are formed on the lower surface 412b of the first substrate 412. The plurality of external interconnection bumps 460 are electrically coupled with the first interconnection pattern 414.

In some embodiments, an electrically conductive bump material is deposited over the first interconnection pattern 414 which is exposed from the lower surface 412b of the first substrate 412 using one of or any combination of the following processes: evaporation, electrolytic plating, electroless plating, ball drop, or screen printing process. The conductive bump material can be solder, Al, Sn, Ni, Au, Ag, Pb, Bi, Cu, or combinations thereof, with an optional flux solution. For example, the bump material can be eutectic Sn/Pb, high-lead solder, or lead-free solder.

In some embodiments, the bump material may be reflowed by heating the material above its melting point to form the external interconnection balls or bumps 460. In some embodiments, the external interconnection balls or bumps 460 may be compression bonded or thermocompression bonded to the first interconnection pattern 414 exposed from the lower surface 412b. The spherical bumps 460 shown in FIG. 4G may represent one type of external interconnection bumps that can be formed on the lower surface 412b of the first substrate 412. In other examples, the external interconnection bumps 460 may be a stud bump, a micro bump, or other electrical interconnects.

Afterwards, as shown in FIG. 4H, a singulation process is performed to singulate each individual package from the package strip along the singulation channels. For example, the package strip can be singulated into individual packages through the singulation channels using a saw blade. In some other examples, a laser cutting tool can also be used to singulate the package strip.

At last, referring to FIG. 4I, an electromagnetic interference (EMI) shield 470 is formed to cover the second sub-package 440 and lateral surfaces of the first sub-package 410.

The EMI shield 470 may be formed from copper, aluminum, iron, or any other suitable material for EMI shielding. In some embodiments, the EMI shield 470 may be formed by spray coating, plating, sputtering, or any other suitable metal deposition process. The EMI shield 470 may follow the shapes and/or contours of the second sub-package 440 and the lateral surfaces of the first sub-package 410.

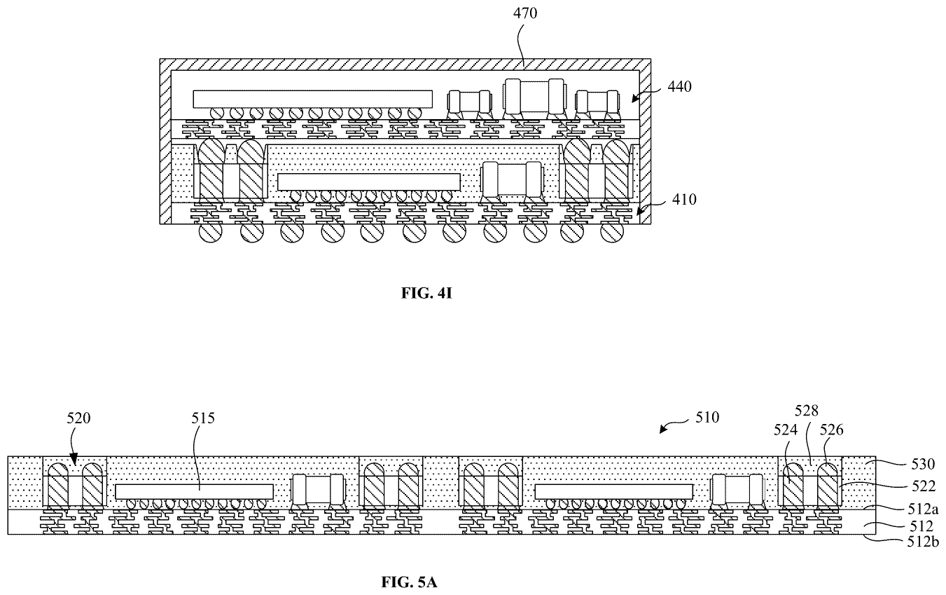

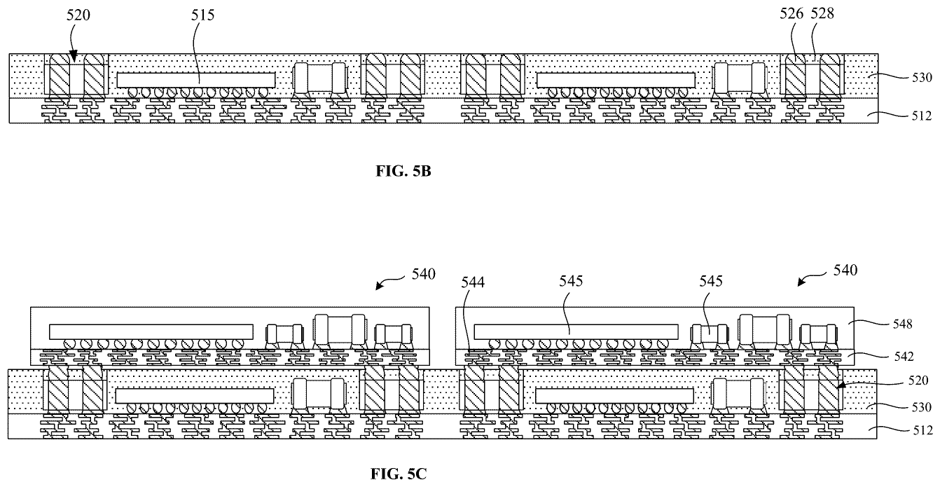

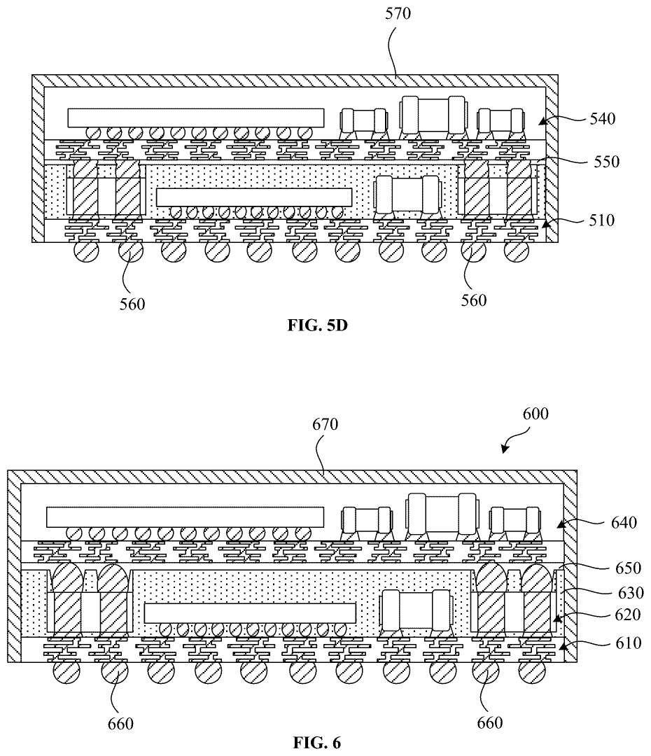

Referring to FIGS. 5A to 5D, cross-sectional views illustrating a method for making a PoP type package are shown according to another embodiment of the present application.

As shown in FIG. 5A, a first sub-package 510 is provided. The first sub-package 510 may include a first substrate 512 having an upper surface 512a and a lower surface 512b, at least one first interconnection pattern 514 formed in the first substrate 512, and at least one first electronic component 515 mounted on an upper surface 512a of the first substrate 512. At least one modular interconnection unit 520 is mounted on the upper surface 512a of the first substrate 512. The modular interconnection unit 520 may include a dielectric layer 522, at least one conductive via 524 passing through the dielectric layer 522, and at least one conductive bump 526 disposed on the dielectric layer 522 and raised from an upper surface of the dielectric layer 522. The modular interconnection unit 520 further include a protection layer 528 covering the conductive bump 526 and having a flat upper surface. A first encapsulant 530 is formed on the upper surface of the first substrate 512 to encapsulate the first electronic component 515 and the modular interconnection unit 520. The package structure shown in FIG. 5A is similar to the structure shown in FIG. 4C, and will not be elaborated herein.

Afterwards, referring to FIG. 5B, the protection layer 528 of the modular interconnection unit 520 is grinded to expose the conductive bump 526.

In some embodiments, an upper portion of the first encapsulant 530 and an upper portion of the protection layer 528 are simultaneously removed by a grinder. The grinding process can also planarize upper surfaces of the first encapsulant 530 and the protection layer 528. In some cases, an upper portion of the conductive bump 526 is also removed in the grinding process to expose more area of the conductive bump 526.

Referring to both FIG. 5B and FIG. 5C, at least one second sub-package 540 is mounted on the modular interconnection unit 520 and above the first encapsulant 530.

The second sub-package 540 may include a second substrate 542, at least one second interconnection pattern 544 formed in the second substrate 542, and at least one second electronic component 545 mounted on an upper surface of the second substrate 542. Further, the second sub-package 540 may include a second encapsulant 548 encapsulating the second electronic component 545. In some embodiments, solder paste may be deposited or printed onto the conductive bump 526 exposed from the first encapsulant 530 and the protection layer 528. Then, the second sub-package 540 may be placed on the first encapsulant 530 with terminals or contacts of the second sub-package 540 in contact with and over the solder paste. The solder paste may then be reflowed to mechanically and electrically couple the second sub-package 540 to the conductive bump 526.

Afterwards, referring to FIG. 5D, an underfill encapsulant 550 is formed between the second sub-package 540 and the first sub-package 510, a plurality of external interconnection bumps 560 are formed on the lower surface of the first substrate 510, and then a singulation process is performed to singulate each individual package from the package strip. At last, an EMI shield 570 is formed to cover the second sub-package 540 and lateral surfaces of the first sub-package 510.

According to another aspect of the present application, a semiconductor package is provided.

Referring to FIG. 6, a cross-sectional view of a semiconductor package 600 is illustrated according to an embodiment of the present disclosure. The semiconductor package 600 may include a first sub-package 610, at least one modular interconnection unit 620, a first encapsulant 630, and a second sub-package 640.

The first sub-package 610 may include a first substrate, at least one first interconnection pattern formed in the first substrate, and at least one first electronic component mounted on an upper surface of the first substrate. The modular interconnection unit 620 may be mounted on the upper surface of the first substrate. The modular interconnection unit 620 may include a dielectric layer, at least one conductive via passing through the dielectric layer, at least one conductive bump disposed on the dielectric layer and raised from an upper surface of the dielectric layer, and a protection layer disposed on the dielectric layer and partially covering the conductive bump. The conductive via is electrically coupled with the first interconnection pattern, and an upper surface of the conductive bump is exposed from the protection layer. The first encapsulant 630 is disposed on the upper surface of the first substrate, and the first encapsulant 630 surrounds the first electronic component and the modular interconnection unit 620, and exposes the upper surface of the conductive bump. The second sub-package 640 is mounted above the first encapsulant 630. The second sub-package 640 may include a second substrate, at least one second interconnection pattern formed in the second substrate, and at least one second electronic component mounted on an upper surface of the second substrate, and the second interconnection pattern is electrically coupled with the conductive via. The second sub-package 640 may further include a second encapsulant disposed on the upper surface of the second substrate and encapsulating the second electronic component.

In some embodiments, the semiconductor package 600 may further include an underfill encapsulant 650 between the first encapsulant and the second substrate.

In some embodiments, the semiconductor package 600 may further include a plurality of external interconnection bumps 660 formed on a lower surface of the first substrate. The plurality of external interconnection bumps 660 are electrically coupled with the first interconnection pattern.

In some embodiments, the semiconductor package 600 may further include an EMI shield 670 covering the second sub-package 640 and lateral surfaces of the first sub-package 610.

The semiconductor package 600 can be formed by the steps illustrated in FIGS. 4A to 4I, or the steps illustrated in FIGS. 5A to 5D. Thus, more details about the semiconductor package 600 may refer to the above method embodiments, and will not be elaborated herein.

While the semiconductor package of the present application is described in conjunction with corresponding figures, it will be understood by those skilled in the art that modifications and adaptations to the semiconductor package may be made without departing from the scope of the present invention.

The discussion herein included numerous illustrative figures that showed various portions of a semiconductor package and a method for making the same. For illustrative clarity, such figures did not show all aspects of each example package. Any of the example packages and/or methods provided herein may share any or all characteristics with any or all other devices and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming a semiconductor package, comprising:
providing a first sub-package comprising a first substrate, at least one first interconnection pattern formed in the first substrate, and at least one first electronic component mounted on an upper surface of the first substrate;
mounting at least one modular interconnection unit on the upper surface of the first substrate, wherein the modular interconnection unit comprises a dielectric layer, at least one conductive via passing through the dielectric layer, at least one conductive bump disposed on the dielectric layer and raised from an upper surface of the dielectric layer, and a protection layer covering the conductive bump and having a flat upper surface, and wherein the conductive via is electrically coupled with the first interconnection pattern;
forming a first encapsulant on the upper surface of the first substrate to encapsulate the first electronic component and the modular interconnection unit;
removing a portion of the protection layer to expose an upper surface of the conductive bump; and
mounting a second sub-package above the first encapsulant, wherein the second sub-package comprises a second substrate, at least one second interconnection pattern formed in the second substrate, and at least one second electronic component mounted on an upper surface of the second substrate, and the second interconnection pattern is electrically coupled with the conductive bump.

2. The method of claim 1, wherein mounting the modular interconnection unit on the upper surface of the first substrate further comprises:
performing a pick-and-place operation using a vacuum pick-and-place tool to move the modular interconnection unit to a location above the first interconnection pattern.

3. The method of claim 1, wherein removing a portion of the protection layer to expose the conductive bump comprises:
performing a laser ablation process on the protection layer to expose the conductive bump.

4. The method of claim 1, wherein removing a portion of the protection layer to expose the conductive bump comprises:
grinding the protection layer to expose the conductive bump.

5. The method of claim 1, further comprising:
forming an underfill encapsulant between the first encapsulant and the second substrate.

6. The method of claim 1, further comprising:
forming a plurality of external interconnection bumps on a lower surface of the first substrate, wherein the plurality of external interconnection bumps are electrically coupled with the first interconnection pattern.

7. The method of claim 1, further comprising:
forming an electromagnetic interference (EMI) shield to cover the second sub-package and lateral surfaces of the first sub-package.

8. A semiconductor package, comprising:
a first sub-package comprising a first substrate, at least one first interconnection pattern formed in the first substrate, and at least one first electronic component mounted on an upper surface of the first substrate;
at least one modular interconnection unit mounted on the upper surface of the first substrate, wherein the modular interconnection unit comprises a dielectric layer, at least one conductive via passing through the dielectric layer, at least one conductive bump disposed on the dielectric layer and raised from an upper surface of the dielectric layer, and a protection layer disposed on the dielectric layer and partially covering the conductive bump, wherein the conductive via is electrically coupled with the first interconnection pattern, and wherein an upper surface of the conductive bump is exposed from the protection layer;
a first encapsulant disposed on the upper surface of the first substrate, wherein the first encapsulant surrounds the first electronic component and the modular interconnection unit, and exposes the upper surface of the conductive bump; and
a second sub-package mounted above the first encapsulant, wherein the second sub-package comprises a second substrate, at least one second interconnection pattern formed in the second substrate, and at least one second electronic component mounted on an upper surface of the second substrate, and the second interconnection pattern is electrically coupled with the conductive bump.

9. The semiconductor package of claim 8, further comprising:
an underfill encapsulant formed between the first encapsulant and the second substrate.

10. The semiconductor package of claim 8, further comprising:
a plurality of external interconnection bumps formed on a lower surface of the first substrate, wherein the plurality of external interconnection bumps are electrically coupled with the first interconnection pattern.

11. The semiconductor package of claim 8, further comprising:
an electromagnetic interference (EMI) shield covering the second sub-package and lateral surfaces of the first sub-package.

12. The semiconductor package of claim 8, further comprising:
a second encapsulant disposed on the upper surface of the second substrate and encapsulating the second electronic component.

13. A modular interconnection unit, comprising:
a dielectric layer;
at least one conductive via passing through the dielectric layer;
at least one conductive bump disposed on the dielectric layer and raised from an upper surface of the dielectric layer; and
a protection layer disposed on the dielectric layer, wherein the protection layer covers the conductive bump and has a flat upper surface.

14. The modular interconnection unit of claim 13, wherein a thickness of the protection layer ranges from 105% to 200% of a height of the conductive bump.

15. The modular interconnection unit of claim 13, wherein the protection layer comprises a molding compound.
